(19) United States
(12) Patent Application Publication
(10) Pub. No.: US 2007/0057330 A1
(43) Pub. Date: Mar. 15, 2007

(54) Semiconductor device and method of fabricating semiconductor device

(75) Inventor: Joo Hyun Lee, Icheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU ELECTRONICS CO., LTD.

(21) Appl. No.: 11/521,306

(22) Filed: Sep. 15, 2006

(30) Foreign Application Priority Data
Sep. 15, 2005 (KR) 10-2005-0086098

(51) Int. Cl. H01L 29/76

(52) U.S. Cl. 257/382

(57) ABSTRACT

A semiconductor device is provided. The semiconductor device includes a substrate, a gate, spacers, and a source and a drain. The gate is formed on the substrate, has side walls, and is formed of a silicide material. The spacers are formed on the sidewalls of the gate. The source and the drain are formed on the substrate. The gate protrudes above the spacers.

### RELATED APPLICATION

This application is based upon and claims the benefit of priority to Korean Application No. 10-2005-0086098, filed on Sep. 15, 2005, the entire contents of which are incorporated herein by reference.

### BACKGROUND

1. Technical Field

The present invention relates to a semiconductor device and a method of fabricating the semiconductor device.

2. Description of the Related Art

The performance of a transistor in a semiconductor device depends upon factors such as the speed, drive current, and leakage current of the transistor. In order to achieve a higher speed and lower leakage current, it is beneficial to lower the resistance of the source, drain, gate, and contact portion of the transistor.

In order to lower the resistance in the aforementioned regions, a silicide layer is formed on the interface of the drain and source, and on the interface of the gate. The silicide layer is generally formed of a compound of a metal and silicon, for example, titanium silicide (TiSi₂), lead silicide (PbSi₂), cobalt silicide (CoSi₂), and nickel silicide (NiSi₂).

In a semiconductor device including such a silicide layer, a gate is formed on a substrate, and a sacrifice layer is formed to cover the gate. Next, the sacrifice layer is removed through a chemical mechanical polishing (CMP) process to expose the upper surface of the gate. A metal layer is formed on the gate and then heat-treated to be silicided.

However, the CMP process causes defects, i.e., scratches, residues, etc., on the upper surface of the gate. Also, the stress between a poly layer and a gate oxide layer increases during the polishing process, thereby deteriorating the interface characteristics of the semiconductor device.

### SUMMARY

Accordingly, embodiments consistent with the present invention are directed to a semiconductor device and a method of fabricating the semiconductor device that substantially obviates one or more problems due to limitations and disadvantages of the related art.

An embodiment consistent with the present invention provides a semiconductor device capable of preventing a deterioration of the electrical characteristics of the semiconductor device by minimizing scratches and residues on the gate surface and reducing stress in the polishing process when forming a silicide layer.

Additional advantages and features of the invention will be set forth in part in the description which follows and in part will become apparent to those having ordinary skill in the art upon examination of the following or may be learned from practice of the invention. The features and other advantages of the invention may be realized and attained by the structure particularly pointed out in the written description and claims hereof as well as the appended drawings.

Consistent with the present invention, as embodied and broadly described herein, there is provided a semiconductor device including: a substrate; a gate formed on the substrate, the gate having sidewalls and being formed of a silicide material; spacers formed on the sidewalls of the gate; and a source and a drain formed on the substrate, wherein the gate protrudes above the spacers.

In another embodiment consistent with the present invention, there is provided a method of fabricating a semiconductor device, the method including: stacking a gate oxide layer, a poly-Si (polycrystal silicon) layer, and a hard mask on a substrate, the poly-Si layer having sidewalls; forming spacers on the sidewalls of the poly-Si layer; forming a source and a drain on the substrate using an epitaxial method; implanting a high concentration of conduction type impurity ions into the source and the drain; forming a silicide layer on the source and the drain; forming a sacrifice layer on the substrate; polishing the sacrifice layer and the hard mask using a chemical mechanical polishing (CMP) process until the hard mask is polished to a predetermined thickness; and removing the remaining portion of the hard mask using a wet etching process to expose an upper surface of the poly-Si layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the present invention and are incorporated in and constitute a part of this application, illustrate embodiment(s) consistent with the present invention and together with the description serve to explain the principle of the present invention. In the drawings:

FIG. 1 is a sectional view of a semiconductor device consistent with an embodiment of the present invention; and

FIGS. 2 to 7 are sectional views sequentially showing a method of fabricating a semiconductor device consistent with an embodiment of the present invention.

### DETAILED DESCRIPTION

Reference will now be made in detail to the preferred embodiments of the present invention, examples of which are illustrated in the accompanying drawings. Wherever possible, the same reference numbers will be used throughout the drawings to refer to the same or like parts.

In the figures, the dimensions of layers and regions may be exaggerated for clarity of illustration. Like reference numerals refer to like elements throughout. It will be understood that when an element such as a layer, a film, a region, a plate, or the like, is referred to as being “on” another element, it can be directly on the other element, or intervening elements may also be present. It will also be understood that when an element is referred to as being “directly on” another element, intervening elements cannot be present.

Hereinafter, an embodiment consistent with the present invention is described in conjunction with the accompanying drawings.

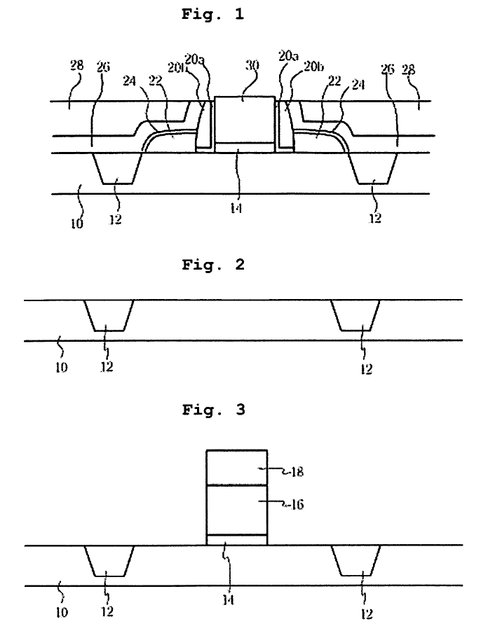

FIG. 1 is a sectional view of a semiconductor device consistent with an embodiment of the present invention.

Referring to FIG. 1, device isolation regions 12 are formed in a semiconductor substrate 10 to define an active region. A gate oxide layer 14 is formed on a portion of the active region, and a gate 30 is formed on gate oxide layer 14. Gate 30 may be formed of nickel silicide (NiSi₂) or cobalt silicide (CoSi₂).

Buffer layers 20a and spacers 20b are formed on the sidewalls of gate 30. Buffer layers 20a are formed of an oxide material, and spacers 20b are formed of a nitride material. Buffer layers 20a reduce stress between gate 30 and spacers 20b.

A source and a drain 22 doped with n-type or p-type impurities of high concentration are formed in portions of semiconductor substrate 10 that are located on both sides of gate 30 and spacers 20b.

Silicide layers 24 are formed on source and drain 22. Silicide layers 24 may be formed of NiSi₂ or CoSi₂.

Hereinafter, a method of fabricating the semiconductor device consistent with an embodiment of the present invention will be described in detail with reference to the accompanying drawings.

FIGS. 2 to 7 are sectional views sequentially showing a method of fabricating a semiconductor device consistent with an embodiment of the present invention.

Referring to FIG. 2, device isolation regions 12 are formed of an insulating material in semiconductor substrate 10 by a local oxidation of silicon (LOCOS) process or a shallow trench isolation (STI) process. When forming device isolation regions 12 using a LOCOS process, device isolation regions 12 are formed by partially growing oxide layers in a predetermined region of substrate 10. When forming device isolation regions 12 using an STI process, device isolation regions 12 are formed by first forming trenches in a predetermined region of substrate 10 and then filling the trenches with an insulating material.

Referring to FIG. 3, substrate 10 is oxidized to form an oxide layer on substrate 10. Subsequently, a stacked polycrystal silicon (poly-Si) and oxide structure is formed, wherein a poly-Si layer is formed on the oxide layer and another oxide layer is formed on the poly-Si layer by, for example, a chemical vapor deposition (CVD) process. The poly-Si layer is formed to have a thickness of about 1000 to 2000 Å.

Next, the oxide layer, the poly-Si layer, and the oxide layer are sequentially patterned by selective etching to form a hard mask 18, a poly-Si pattern 16, and a gate oxide layer 14, respectively.

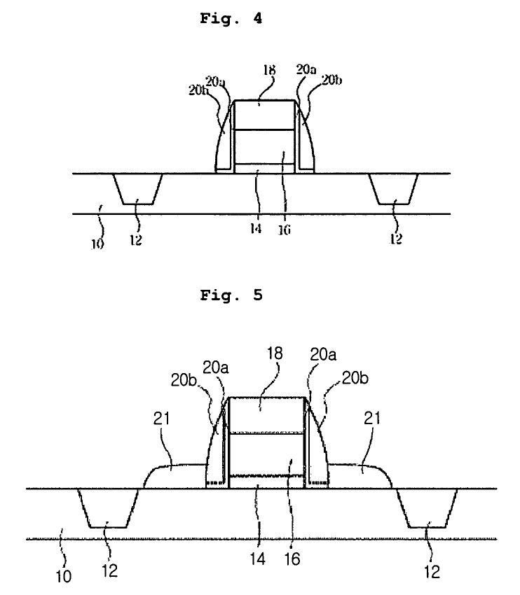

Referring to FIG. 4, an oxide layer and a nitride layer are formed on an entire surface of the substrate 10. An etch-back process is then performed on the oxide layer and the nitride layer to form spacers 20b and buffer layers 20a. Although not shown, an implantation process for implanting ions into substrate 10 may be performed before forming the spacers 20b and buffer layers 20a.

Referring to FIG. 5, silicon layers 21 are formed on exposed portions of substrate 10 by a selective epitaxial method. Silicon layers 21 are subsequently doped with a high concentration of conductive impurity ions and then heat-treated to form source and drain 22.

The ions to be implanted may be n-type or p-type impurities, for example, arsenic (As), phosphorus (P), boron (B), or the like.

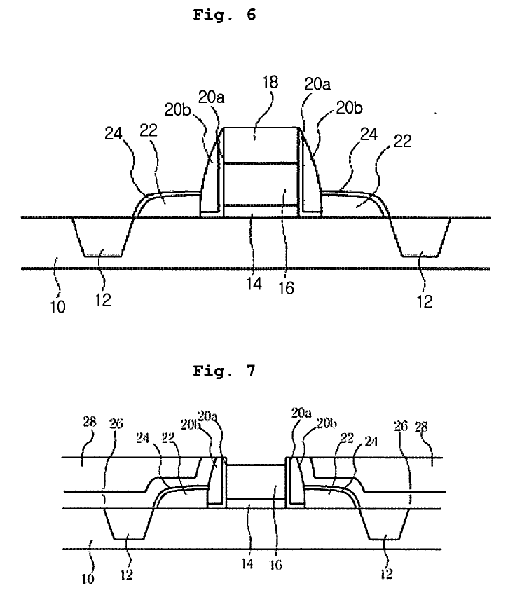

Referring to FIG. 6, a natural oxide layer (not shown) resulting from the selective epitaxial process is removed from substrate 10 using, for example, a solution containing diluted hydrogen fluorine (HF). Cobalt (Co) is then deposited on substrate 10, and then a first heat treatment is performed on substrate 10 to form silicide layers 24 on source and drain 22.

Silicide layers 24 may be formed to have a thickness below 20 Å. Moreover, the first heat treatment may be performed in a chamber having a nitrogen atmosphere at a temperature of about 400 to 600° C. for a period of about 2 minutes.

The cobalt that has not been silicided may be removed using a wet cleaning process that uses a sulfuric peroxide mixture (SPM) or a standard clean 1 (SC1) solution. The SC1 is ammonium hydroxide (NH₄OH) or a mixture of trimethyl-oxyethyl ammonium hydroxide (TMH), hydrogen peroxide (H₂O₂), and hydrogen oxide (H₂O). The cleaning is performed for about 5 to 25 minutes. In order to stabilize the silicide layers, a second heat treatment may be performed in a nitrogen atmosphere at a temperature of about 720 to 920° C. for a period of time of about 2 minutes.

Referring to FIG. 7, first and second sacrifice layers 26 and 28 are formed to cover substrate 10, silicide layers 24, spacers 20b, and hard mask 18. First and second sacrifice layers 26 and 28 may be formed of an oxide material and a nitride material, respectively.

Second sacrifice layer 28, first sacrifice layer 26, and the hard mask 18 are then polished using a CMP process until hard mask 18 has a thickness of about 50 Å or less.

Hard mask 18 is then removed by a wet etching process to expose poly-Si pattern 16. A diluted HF solution, phosphoric acid (H₃PO₄), SC1, or SPM may be used in the wet etching process. Here, the HF is diluted at a H₂O:HF ratio of about 100:1 to 200:1, and the H₃PO₄ has a concentration of about 80 to 90%. The SPM is a 1:1 mixture of sulfuric acid to hydrogen peroxide (H₂SO₄:H₂O₂).

As described above, an upper surface of poly-Si pattern 16 is exposed by a wet etching process, not polishing, reducing the damage to the surface of poly-Si pattern 16. Also, as hard mask 18 is removed, poly-Si pattern 16 has a predetermined height difference with respect to first and second sacrifice layers 26 and 28. A gate comprising poly-Si pattern 16 is able to expand up to second sacrifice layer 28 decreasing stresses that may occur.

Referring to FIG. 1 again, nickel is deposited on the entire surface of substrate 10 to form a nickel metal layer, and then a first heat treatment is performed on substrate 10 to form gate 30.

Since the volume of the nickel metal layer expands about 2 to 3 times during the first heat treatment, the poly-Si layer is formed to a thickness such that the poly-Si layer is sufficiently silicided. For example, if the poly-Si layer is formed to a thickness of 1500 Å, then the nickel metal layer may be formed to a thickness of 600 to 800 Å. Gate 30 may then protrude above spacers 20a, such that the thickness of the protruding portion of gate 30 is approximately 350 to 1350 Å. That is, the height of the top surface of gate 30 may be about 350 to 1350 Å higher than the height of the top surface of spacers 20a.

Next, the portion of the nickel metal layer that was not silicided is removed, and gate 30 is heat-treated a second time to stabilize the silicide included in gate 30. The method of forming a nickel silicide layer is the same as the method of forming a cobalt silicide layer as illustrated in FIG. 6.

A natural oxide layer (not shown) may be formed on a surface of the poly-Si pattern 16 before forming gate 30, but may be removed when etching hard mask 18, and thus a separate cleaning may be omitted.

As described above, portions of the hard mask remaining on the gate may be removed using a wet-etching process thereby reducing the damage to the surface of the gate that would be caused by using a polishing process. Also, by reducing the polishing time, stress between the gate and the gate oxide layer can also be reduced to prevent the deterioration of interface characteristics between the gate and the gate oxide layer resulting in a high quality semiconductor device fabricated with optimal electrical characteristics.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A semiconductor device comprising:
a substrate;
a gate formed on the substrate, the gate having sidewalls and being formed of a silicide material;
spacers formed on the sidewalls of the gate; and
a source and a drain formed on the substrate,
wherein the gate protrudes above the spacers.

2. The semiconductor device according to claim 1, further comprising a silicide layer formed on the source and the drain.

3. The semiconductor device according to claim 1, wherein the source and the drain are silicon layers formed by an epitaxial method.

4. The semiconductor device according to claim 1, wherein the silicide material is a nickel silicide.

5. The semiconductor device according to claim 2, wherein the silicide layer formed on the source and the drain is a cobalt silicide layer.

6. The semiconductor device according to claim 1, wherein the gate protrudes about 350 to 1,350 Å above the spacers.

7. The semiconductor device according to claim 1, further comprising first and second sacrifice layers formed on the substrate, the first and second sacrifice layers being formed to not cover the gate.

8. The semiconductor device according to claim 7, wherein the first and second sacrifice layers are formed of an oxide material and a nitride material, respectively.

9. A method of fabricating a semiconductor device, the method comprising:
stacking a gate oxide layer, a poly-Si (polycrystal silicon) layer, and a hard mask on a substrate, the poly-Si layer having sidewalls;
forming spacers on the sidewalls of the poly-Si layer;
forming a source and a drain on the substrate using an epitaxial method;
implanting a high concentration of conduction type impurity ions into the source and the drain;
forming a silicide layer on the source and the drain;
forming a sacrifice layer on the substrate;
polishing the sacrifice layer and the hard mask using a chemical mechanical polishing (CMP) process until the hard mask is polished to a predetermined thickness; and
removing the remaining portion of the hard mask using a wet etching process to expose an upper surface of the poly-Si layer.

10. The method according to claim 9, further comprising forming a metal layer on the exposed upper surface of the poly-Si layer; and
siliciding the metal layer.

11. The method according to claim 9, wherein polishing comprises polishing the hard mask to a thickness of 50 Å or less.

12. The method according to claim 9, wherein the forming of the silicide layer comprises:
depositing nickel or cobalt to form a metal layer; and
siliciding the metal layer.

13. The method according to claim 9, wherein the sacrifice layer is formed of one of an oxide material or a nitride material.

14. The method according to claim 9, wherein removing the remaining portion of the hard mask comprises performing a wet eching process using one of a HF solution diluted at a H₂O:HF ratio of 100:1 to 200:1, or phosphoric acid (H₃PO₄) having a concentration of 80 to 90%.

15. The method according to claim 9, wherein removing the remaining portion of the hard mask comprises etching the poly-Si layer such that the poly-Si layer has a predetermined height difference with respect to the sacrifice layer.
